(19) United States
(12) Patent Application Publication
(10) Pub. No.: US 2025/0321257 A1
(43) Pub. Date: Oct. 16, 2025

(54) ELECTROMAGNETIC FIELD STIRRER FOR AN EMC TEST ENCLOSURE

(71) Applicant: COMPAGNIE GENERALE DES ETABLISSEMENTS MICHELIN, Clermont-Ferrand (FR)

(72) Inventors: LUDOVIC VOLLET, Clermont-Ferrand (FR); LISE MANGIN, Clermont-Ferrand (FR)

(21) Appl. No.: 18/866,327

(22) PCT Filed: May 16, 2023
(86) PCT No.: PCT/EP2023/063073

§ 371 Date: Nov. 15, 2024

(30) Foreign Application Priority Data
May 16, 2022 (FR) FR2204601

(51) Int. Cl. G01R 29/08

(52) U.S. Cl. CPC G01R 29/0821; G01R 29/0871

(57) ABSTRACT

Mechanical electromagnetic field stirrer (1) for an electromagnetic compatibility test enclosure comprising: a chassis (2) forming a support for a turntable suitable for being coupled to means for rotating the turntable; a mast (11) mounted on the turntable (62); and at least one blade (20, 30, 40, 50) of the field stirrer fastened to the mast and comprising a reflective face. The blade (20, 30, 40, 50) comprises a framework (21, 31, 41, 51) comprising at least one element comprising at least one fabric-based envelope and at least one inflatable tube arranged inside the at least one envelope.

The present invention relates to the field of enclosures for testing the electromagnetic compatibility of the electronic equipment in apparatus or equipment in the aerospace, aeronautical, automotive or civil sectors. These test enclosures are also known as Faraday cage enclosures. The invention relates more particularly to a mechanical device for stirring the electromagnetic waves in such a test enclosure.

An electromagnetic compatibility (EMC) test enclosure must measure the electromagnetic compatibility of an apparatus or the electronic components thereof. It is a Faraday cage test enclosure (or Faraday tent), which is an enclosed space delimited by walls that have high electrical conductivity or are covered with a metal or metallized envelope having high electrical conductivity.

The various items of electronic equipment in a motor vehicle, aircraft or satellite interact electromagnetically with each other and with their environment, as they experience interference from the environment and can also interfere with it. As a result, their electromagnetic compatibility must be checked to ensure that they operate satisfactorily with each other and in a given electromagnetic environment, which is often hostile. Immunity and emission tests are thus performed in response to regulatory requirements and standards in force in the relevant sector, in an EMC test enclosure.

More particularly, during these tests, the electronic equipment tested is subjected to strong, pulsed electromagnetic fields over very wide frequency bands. These tests can be performed in an EMC test enclosure provided with mechanical stirring means and thus forming a reverberation chamber. The strong electromagnetic fields (hundreds or thousands of volts) are produced in the enclosure and the incident waves are subjected to multiple reflections produced by a rotating mechanical stirrer against the walls of the enclosure. The mechanical stirrer comprises metal blades fastened to a rotated shaft. The electromagnetic environment thus created by the rotation of the stirrer is statistically isotropic and homogeneous.

CN203643474U discloses an EMC reverberation test chamber comprising a mechanical stirring device and a rotary transmitting antenna device. The mechanical stirring device comprises an assembly of zigzag metal panels supported by the shaft of a metal structure, a first drive motor for rotating the shaft and a device for controlling the motor. During operation, a uniform electromagnetic field is obtained in the reverberation chamber due to the simultaneous rotation of the mechanical stirring device and the antenna. The need for a more efficient stirring device remains.

Another type of mechanical electromagnetic wave stirrer is also known, produced in the form of a metal structure comprising a central shaft provided with a plurality of arms extending radially outwards from the shaft and each supporting blades made from a reflective material. The blades are folded flat panels forming a given angle between them. Such a metal structure involves a very large mass and is difficult to move, especially when it has large dimensions (several metres) so that it is suitable for use in large-volume chambers. The devices in these solutions are heavy and non-modular and have large footprints.

One aim of the invention is to overcome the drawbacks of the aforementioned devices and provide a novel solution for a mechanical device for stirring the electromagnetic waves inside an EMC test enclosure that is very light, can be transported or moved easily, and the structure of which makes it possible to adapt it to test enclosures of different volumes, at a lower cost.

This aim is achieved with a mechanical electromagnetic field stirrer for an electromagnetic compatibility test enclosure comprising:
a chassis forming a support for a turntable suitable for being coupled to means for rotating said turntable;
a mast arranged in the centre of the turntable; and
at least one blade of the field stirrer fastened to the mast and comprising a reflective face, characterized in that said blade comprises a framework comprising at least one element comprising at least one fabric-based envelope and at least one inflatable tube arranged inside said at least one envelope.

In other words, the invention proposes a mechanical device for stirring electromagnetic waves, used to test an apparatus or item of equipment inside an EMC test enclosure and comprising a mast mounted on a turntable and rigidly connected thereto for conjoint rotation, suitable for being rotated about its longitudinal axis, the mast comprising at least one blade with a reflective face for reflecting the electromagnetic waves, the blade comprising a framework produced using one or more elements, each comprising at least one inflatable tube arranged inside a fabric envelope, the different elements forming separate air chambers. Preferably, one element comprises a closed envelope produced by assembling a plurality of pieces of fabric together, said envelope comprising an opening through which an inflatable tube can be inserted. The elements thus formed become rigid when the tubes are inflated. A fabric blade is thus obtained that holds its shape and can rotate with the mast when the mast is rotated, which makes it possible to mix the electromagnetic waves emitted by a test device situated in the enclosure by sending them towards the reflective walls of the enclosure, and thus create a uniform field.

Framework is given to mean a set of rigid elements that form a support for other components of the blade and also allows the assembly thereof on the mast. The framework of a blade of the invention comprises first peripheral rigid elements that define the outline of a blade and it can additionally comprise two reinforcing elements therefore situated inside the outline formed by the first elements and connected thereto. By way of example, the framework of a polygonal blade comprises first peripheral elements defining the outline of the polygon, each element containing an inflatable tube, and second elements containing inflatable tubes can be situated inside the polygon, in particular to ensure the stiffness of the framework of the blades with large dimensions.

The framework produced using fabric elements containing tubes acting as air

chambers has the advantage of being very light, requiring quite low inflation pressure (less than 0.4 bar) and therefore being able to take shape quickly by inflation, while facilitating the repair or replacement of a damaged tube. The service life of the stirrer is thus improved. The framework of the blade can then be covered or enveloped in a reflective fabric, which means that the blade as a whole is very light, and allows the stirrer comprising it to be transported easily with a view to the use thereof. Such a folded blade is thus light and easy for an operator to transport by hand, and requires just a few minutes to inflate. The stirrer comprising it can thus be installed quickly in an EMC test enclosure, while requiring little storage space. In addition, a lighter structure of the mast and blade assembly allows the use of a less powerful motor for rotating it, which thus makes it possible to reduce electricity consumption.

Such a blade having an inflatable framework can therefore switch easily from an inflated state in which it has a significant span, for example of several metres, to a deflated state in which it occupies a very small volume.

The mast can comprise a fabric mast envelope and an inflatable tube arranged inside the mast envelope. The envelope can be made from an electrically conductive fabric or be covered therewith. This makes it possible to have an inflatable structure of the assembly formed by the mast and the blades, for an even lower weight and easier transport of the assembly. Such a mast and blade assembly having an inflatable structure is extremely compact in the deflated state; it can be transported in a rucksack and, taking into account the low inflation pressure, takes around 15 minutes to inflate, even for a span of the assembly of several metres.

The fabric of the elements of the framework can comprise synthetic textile fibres, for example Dacron®, and said inflatable tube can comprise polyurethane. This makes it possible to obtain a framework having a low weight, while having satisfactory mechanical strength.

The framework of said blade can be in the shape of an arch comprising at least two parallel arch-shaped elements each containing at least one inflatable tube and connected to each other by at least two elements forming crossmembers, each containing at least one inflatable tube. This makes it possible to obtain satisfactory stiffness of an arch-shaped framework after inflation of the tubes.

The stirrer can comprise at least two blades extending radially relative to the central axis of the mast and arranged substantially angularly equidistant from each other. Arranged substantially angularly equidistant from each other is given to mean that the blades form between them an angle equal to 360° divided by the number of blades, with a tolerance of ±20°. A plurality of blades uniformly distributed over the circumference of the mast thus allows improved stirring of the electromagnetic field in the EMC test enclosure.

The stirrer can comprise at least two blades of different shapes and/or dimensions. This makes it possible to further improve the stirring of the electromagnetic field in the EMC test enclosure.

The mast can have a cylindrical shape and the blade(s) can be fastened to the generatrix of the mast by an element of their framework, the mast being able to be provided with fasteners that interact with complementary fasteners on the blades. This makes it possible to attach the blades to, or, when the fasteners are removable, to detach the blades from the mast, while making it possible to obtain a large span of the assembly for optimized stirring of the waves inside the EMC test enclosure.

The fasteners of the mast and the complementary fasteners of the blades can comprise one or more slide fasteners. Such a slide or zip fastener makes it possible to attach and detach the blades easily to and from the mast, while ensuring precise relative positioning of the different elements thus assembled.

The framework of the blade can be covered with an electrically conductive material. The framework can be enveloped in such an electrically conductive material capable of reflecting the electromagnetic waves, or it can be secured to the framework, for example permanently by stitching or detachably, in particular using a hook and loop or Velcro® fastening.

The envelope of the mast can be rigidly connected to a rigid plate suitable for being removably fastened to said turntable. This makes it possible to use the same turntable with different masts, while making the mast easy to transport. The rigid plate fastened to the base of the mast contributes to the stability of the mast and of the blades that it supports.

Said chassis can be supported by feet that are radially offset outwards relative to the support plate. This solution makes it possible to obtain satisfactory stability of the stirrer assembly, despite the large span of the assembly in its inflated position.

The ends of said feet can be provided with casters. This makes it possible to move the stirrer assembly in the EMC test enclosure.

This object of the invention is also achieved with a method for assembling a mechanical electromagnetic field stirrer for an electromagnetic compatibility test enclosure comprising:
a chassis forming a support for a turntable suitable for being coupled to means for rotating said turntable;
a mast mounted on the turntable;
and at least one blade of the field stirrer fastened to the mast and comprising a reflective face,
wherein said blade comprises a framework comprising at least one element comprising at least one fabric-based envelope and at least one inflatable tube arranged inside said at least one envelope and wherein the method comprises a step of inflating the inflatable tube(s) inside the framework of said blade after having assembled said blade on the mast.

The method of the invention can comprise an additional step of inflating the inflatable tube situated inside the envelope of the mast before it is fastened to the turntable.

The stirrer of the invention can comprise at least first and second blades and said first and second blades are inflated after the mast has been inflated. This allows very quick assembly and forming of the inflatable parts of the stirrer. A mast supporting a plurality of blades with a span of approximately 4 m can thus be inflated in less than 15minutes.

At least one face of the inflatable structure of said at least one blade can be covered with metallic fabric after it has been inflated.

The mast can comprise an inflatable structure and the method can comprise a step of inflating the inflatable structure of the mast and a step of fastening the mast to the turntable.

The invention will be better understood from the rest of the description, which is supported by the following figures:

FIG. 1 is a perspective view of a stirrer assembly according to the invention;

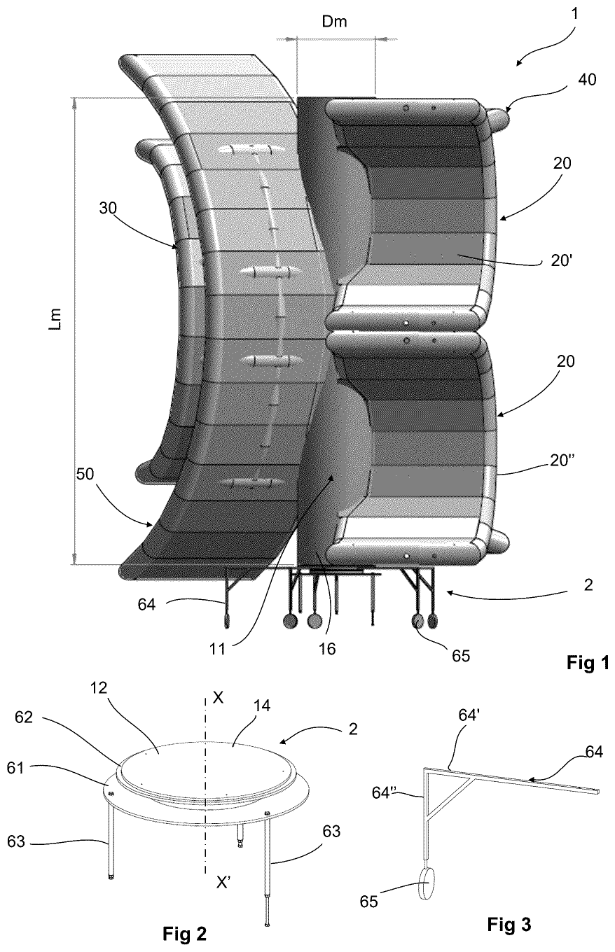

FIG. 2 is a perspective view of a chassis for supporting the structure of the stirrer of the invention;

FIG. 3 is a perspective view a stabilizing arm of the chassis in FIG. 2;

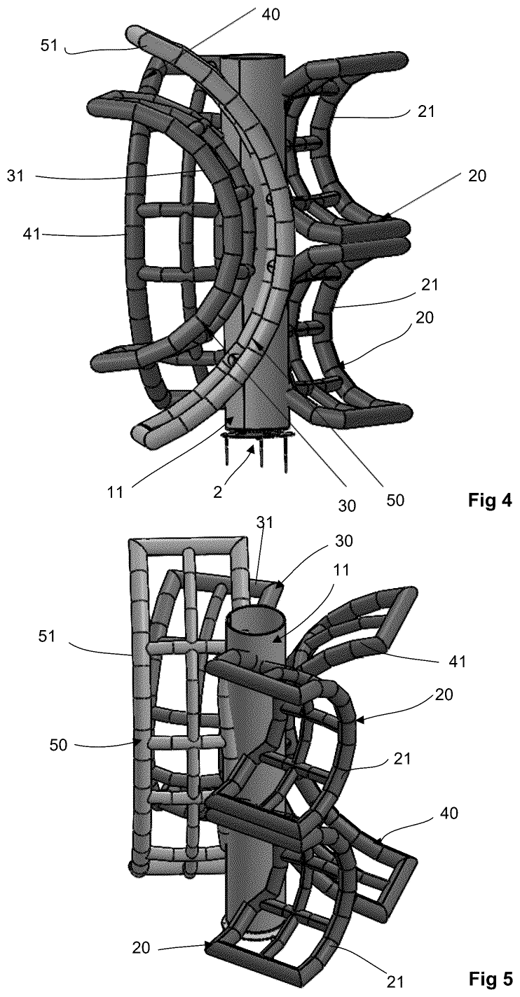

FIG. 4 is a perspective view of a stirrer assembly in FIG. 1, in which the envelope has been removed from the blades in order to reveal their framework;

FIG. 5 is a similar view to FIG. 4 from another angle;

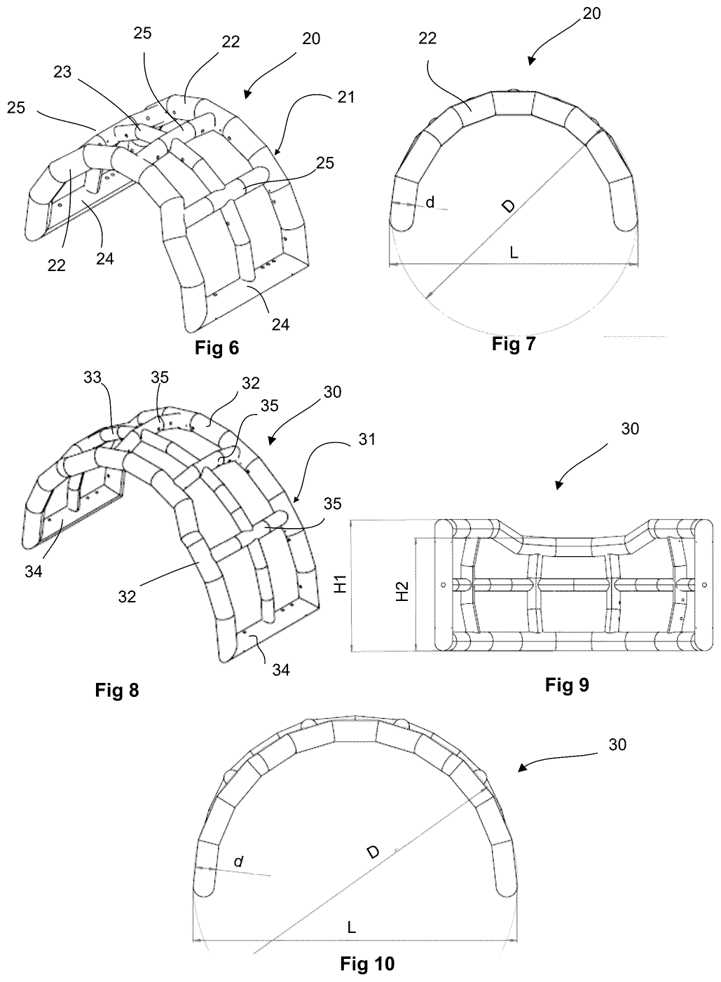

FIG. 6 is a perspective view of the framework of a first blade of the stirrer in FIG. 1, and FIG. 7 is a front view of the blade in FIG. 6;

FIG. 8 is a perspective view of the framework of a second blade of the stirrer in FIG. 1;

FIG. 9 is a bottom view of the same blade and FIG. 10 is a front view of the blade in FIGS. 8 and 9;

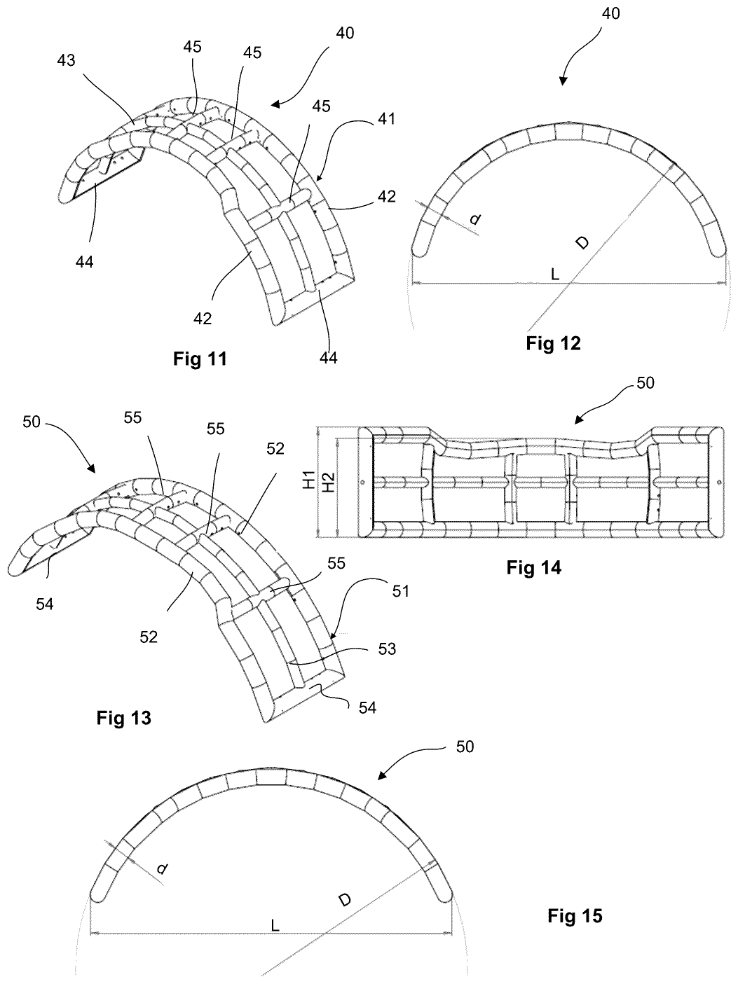

FIG. 11 is a perspective view of the framework of a third blade of the stirrer in FIG. 1, and FIG. 12 is a front view of the blade in FIG. 11;

FIG. 13 is a perspective view of the framework of a fourth blade of the stirrer in FIG. 1;

FIG. 14 is a bottom view of the same blade;

and FIG. 15 is a front view of the blade in FIGS. 13 and 14.

In the various figures, identical or similar elements have the same reference signs. Their description is thus not systematically repeated.

FIG. 1 illustrates a mechanical electromagnetic wave stirrer 1 according to the invention. It is suitable for being installed in an EMC test enclosure. All of the walls, together with the floor and ceiling of such a test enclosure, are made from a metal or metallized material or covered therewith. Such an enclosure can be produced using an inflatable structure covered with a metallized fabric also referred to as Faraday fabric. The device to be tested is installed inside the EMC test enclosure, and means for performing the tests, such as a transmitting antenna connected to a field generator, are installed outside the enclosure. A mechanical stirrer for stirring the electromagnetic field produced is positioned near the transmitting antenna, so that when it rotates, it can intercept and send the waves against the walls of the enclosure in order to mix them and thus homogenize the electromagnetic field in the test enclosure forming a reverberation chamber.

As can be seen in FIG. 1, the stirrer 1 comprises a chassis 2 comprising a supporting plate 61 for a turntable 62 suitable for being coupled to means for rotating the turntable (not illustrated in the figure) about a central axis X-X′ of the turntable, perpendicular to the plane thereof. In the variant in FIG. 2, the supporting plate 61 comprises three supporting rods 63 the height of which can be adjusted, for example by means of a threaded rod that moves inside a threaded stud mounted on the lower surface of the plate 61. In a preferred embodiment of the invention, a plurality of feet 64 are added to the supporting pate 61 and produced so that they are radially offset relative to the perimeter of the supporting plate 61. Each foot 64 comprises a horizontal arm 64′ connected at one of its ends to the plate 61 and, at the opposite end, to a vertical rod 64″ that rests on the ground by means of a caster 65. Radially offset foot is given to mean that the end of the foot bearing the vertical rod protrudes radially relative to the periphery of the plate 61. In a preferred embodiment, the foot 4 is radially offset by a distance at least equal to the radius of the plate 61, five feet 64 thus being positioned equidistant from each other over the perimeter of the plate 61. The role of these feet 64 is to stabilize the stirrer assembly. The vertical rod 64″ can also be height-adjustable and is produced in the same way as the rod 63. The caster 65 is free to rotate and allows easier movement of the chassis 2, and therefore of the stirrer assembly, inside the test enclosure.

The turntable 62 is borne by the supporting plate 61 by means of bearings (not illustrated) and the lower part thereof (given to mean the part on the opposite side from the upper part for receiving the mast of the stirrer) comprises an element for coupling to the output shaft of an electric motor for rotation. Such a motor is preferably an electric stepper motor, powered by an electric battery, and remotely controlled via control electronics. The motor, the power supply battery and the control electronics are contained in a metal housing and positioned under the supporting plate 61 of the chassis 2.

As can be seen in FIG. 1, the mechanical stirrer 1 comprises a mast 11 for supporting at least one blade 20 having a reflective face for reflecting the electromagnetic waves, both the lower face 20′ and upper face 20″ preferably being reflective, and the mast is arranged in the centre of the turntable 62 and rigidly connected thereto for conjoint rotation. More particularly, according to the invention, said at least one blade 20 comprises a framework 21 made up of fabric-based elements each containing at least one inflatable tube. In a preferred embodiment of the invention illustrated in the figures, the stirrer 1 comprises a plurality of blades, namely two identical blades 20, a blade 30, a blade 40 and a blade 50, having different dimensions and shapes, as will be explained hereinafter.

In the example illustrated in the figures, the mast 11 also has an inflatable framework. It comprises an inflatable cylindrical mast envelope 16 made from a flexible material, the envelope being closed at both ends. One of the ends that forms the base of the mast comprises a circular rigid plate 12 (FIG. 2) suitable for being fastened to the turntable 62, for example using screws. FIG. 2 shows the rigid plate 2 fastened to the turntable 62 using a plurality of screws 14, the mast envelope 16 (not illustrated in FIG. 2) being closed on the rigid plate 12. The mast envelope 16 is made from an electrically conductive fabric, or a synthetic fabric such as Dacron® covered with an electrically conductive fabric. The mast envelope 16 contains an inflatable tube made from polyurethane, the tube being provided with a valve making it possible to inflate and deflate it. When it is inflated, the tube situated inside the mast envelope extends between the upper end of the mast and the rigid plate 12, making it possible to form the mast 11. By way of example, the diameter of the mast Dm is approximately 0.7 m, for a height Hm of approximately 4.2 m.

Each blade 20, 30, 40, 50 of the stirrer 1 of the invention comprises an inflatable framework comprising at least two parallel arches connected to each other by a plurality of crossmembers. The framework of the blades of the stirrer can be seen more clearly in FIGS. 4 and 5, in which the outer envelope of the blades has been removed. The stirrer 1 thus comprises three groups of blades distributed over the circumference of the mast 11. A first group is formed by two arch-shaped blades 20 arranged one continuing on from the other on the same first generatix of the mast 11. A second group is formed by another two arch-shaped blades 30 and 50 arranged substantially concentrically on either side of a second generatrix forming an angle of 120° with the first generatrix. A third group comprises a single blade 40 arranged on a third generatrix of the mast 11 situated at 120° to the second and first generatrices of the mast.

FIGS. 6 and 7 illustrate different views of the framework 21 of a blade 20. The framework 21 is formed by two peripheral arches 22, an intermediate arch 23, two sides 24 connecting the base of the arches, and three crossmembers 25 connecting the arches 22 and 23 to each other at different levels from their bases. The peripheral arch 22 and the intermediate arch 23 are each made up of a plurality of pieces of fabric sewn together (the seams are visible in the form of transverse lines in the figures) to form a fabric arch into which is inserted an inflatable tube provided with an inflation valve. Similarly, the sides 24 and the crossmembers 25 are each obtained by sewing pieces of fabric to form a cylindrical side into which is inserted an inflatable tube provided with an inflation valve. The different inflatable tubes are then advantageously connected together (for example using airtight external connecting hoses) in order to facilitate the inflation of the whole framework 21 from a single inflation valve. An inflatable tube is a closed cylindrical tube made from polyurethane, the dimensions of which are substantially those of the envelope into which it is inserted. The framework thus produced is defined by its outer diameter D, its width L and the diameter d of the arch 23. By way of example, the framework 21 has a diameter D of approximately 2 m, a width L of approximately 2 m and an outer diameter d of the arch of approximately 0.2 m. The outer diameter of the sides 24 is substantially equal to the outer diameter d of the peripheral arch 22. The outer diameters of the crossmembers 25 and of the intermediate arches 23 are smaller than the outer diameter of the peripheral arch 22. Similarly to the framework in FIG. 9, which will be described hereinafter, the main arch 23 is flattened at the point at which it is fastened to the generatrix of the mast over a part of the length of the arch between the last two crossmembers 25, the length H1 of the side 24 being approximately 1.4 m and the length H2 of the flattened part begin approximately 1.2 m.

FIGS. 8 to 10 illustrate different views of the framework 31 of a blade 30. The framework 31 is formed by two peripheral arches 32, an intermediate arch 33, two sides 34 connecting the base of the arches, and four crossmembers 35 connecting the arches 32 and 33 to each other at different levels from their bases. The framework elements 31, in particular the arches, the sides and the crossmembers, are produced in a similar way to those of the blade 20, as described above. It will be noted more particularly with reference to FIG. 9 that one of the main arches 33, which is suitable for fastening to the generatrix of the mast 11, is flattened over part of its length between the last two crossmembers 35, corresponding to the dimension H2 in FIG. 9 equal to approximately 1.2 m, for a length of the side H1 of the arch of approximately 1.4 m. By way of example, the framework 31 has a diameter D of approximately 3.1 m, a width L of approximately 3.1 m and a diameter d of the arch of approximately 0.2 m.

FIGS. 11 to 12 illustrate different views of the framework 41 of a blade 40 similar to those described above. The framework 41 is formed by two peripheral arches 42, an intermediate arch 43, two sides 44 connecting the base of the arches, and four crossmembers 45 connecting the arches 42 and 43 to each other at different levels from their bases. The framework elements 41, in particular the arches, the sides and the crossmembers, are produced in a similar way to those of the blade 20, as described above. It will also be noted, as described above, that one of the main arches 43, which is suitable for fastening to the generatrix of the mast 11, is flattened over a length of the arch between the last two crossmembers 45, corresponding to the dimension H2 in FIG. 9 equal to approximately 1.2 m, for a length of the side H1 of the arch of approximately 1.4 m. By way of example, the framework 41 has a diameter D of approximately 4.1 m, a width L of approximately 3.9 m and a diameter d of the arch of approximately 0.2 m.

FIGS. 13 to 15 illustrate different views of the framework 51 of a blade 50 also similar to the preceding frameworks. The framework 51 is formed by two peripheral arches 52, an intermediate arch 53, two sides 54 connecting the base of the arches, and four crossmembers 55 connecting the arches 52 and 53 to each other at different levels from their bases. The framework elements 51, in particular the arches, the sides and the crossmembers, are produced in a similar way to those of the blade 20, as described above.

It will be noted more particularly with reference to FIG. 14 that one of the main arches 53, which is suitable for fastening to the generatrix of the mast 11, is flattened over approximately part of its length between the last two crossmembers 55, corresponding to the dimension H2 in FIG. 14 equal to approximately 1.2 m, for a length of the side H1 of the arch of approximately 1.4 m. By way of example, the framework 31 has a diameter D of approximately 5.1 m, a width L of approximately 4.6 m and a diameter d of the arch of approximately 0.2 m.

The envelope of the elements of the framework 21, 31, 41, 51 is made from a synthetic fabric such as Dacron®. The envelope of each element is closed and produced by sewing a plurality of pieces of fabric together, and an opening allowing the insertion of an inflatable tube is made therein.

The framework of each blade is covered with an electrically conductive fabric. Advantageously, the fabric is secured using hook and loop or Velcro® strips, one part of the strips being sewn to the framework and the other to the fabric covering the blade.

The blades thus obtained are very light. They are evenly distributed over the circumference of the mast, which is already weighted by the rigid plate that fastens it to the turntable and therefore to the chassis, ensuring satisfactory stability. When light blades are added to this mast, evenly distributed over the perimeter of the mast, satisfactory stability of the assembly is obtained. The stability is further increased by means of the feet radially offset towards the outside of the turntable, which ensures satisfactory uniformity on rotation of the stirrer about the vertical longitudinal axis of the mast.

According to one advantageous embodiment of the invention, the mast 11 and the blades 20, 30, 40, 50 are assembled using sliding fasteners (or zip fasteners). To this end, one part of the zip fastener is sewn to the generatrix of the mast and the corresponding part is sewn to one of the arches of the facing blade.

The various parts forming the elements containing inflatable tubes are stored in the deflated state, the blades being detached from the mast to facilitate storage and transport, especially in the case of blades with large dimensions.

When the stirrer is to be operated, the blades and the mast are first assembled using the sliding fasteners. Once they have been assembled, one blade, then the mast, and then the rest of the blades are inflated, with the mast positioned and fastened on its chassis. The inflation pressure of the inflatable tubes inside the mast and blades is approximately 0.2 to 0.35 bar.

During operation, the turntable 62 receives the rotation originating from the rotation means, which are enclosed in a metal housing and comprise a stepper motor powered by a battery and means for controlling the motor. The stirrer is thus rotated according to an established control protocol and, after a predetermined time interval, a homogeneous and isotropic electromagnetic field is obtained in the entire inner volume of the EMC test enclosure.

In one variant, the blades 20 can be arranged one continuing on from the other on the mast 11, but with one of the blades 20 rotated by 180° relative to the other, thus forming an S-shaped blade. A plurality of S-shaped blades can be positioned on the mast 11.

In another variant, the blades 20 are planar, having a polygonal shape, for example rectangular.

Other variants and embodiments of the invention can be envisaged within the scope of the invention as claimed. The blades of the stirrer can thus be in the shape of a portion of a sphere or a portion of a parabola, or any other curved shape. In addition, the mast 11 can be in the shape of a right prism, in order to offer a planar fastening face for the blades of the stirrer. In one variant the mast is rigid, and preferably telescopic.

In addition, a smaller stirrer can be envisaged that is inserted inside an apparatus in order to make the electromagnetic field homogeneous with a view to taking EMC measurements inside the apparatus.

1-15. (canceled)

16. A mechanical electromagnetic field stirrer for an electromagnetic compatibility test enclosure comprising:
a chassis forming a support for a turntable suitable for being coupled to means for rotating the turntable;
a mast mounted on the turntable; and
at least one blade of the mechanical electromagnetic field stirrer fastened to the mast and comprising a reflective face,
wherein the at least one blade comprises a framework comprising at least one element comprising at least one fabric-based envelope and at least one inflatable tube arranged inside the at least one envelope.

17. The mechanical electromagnetic field stirrer according to claim 16, wherein the mast comprises a fabric mast envelope and an inflatable tube arranged inside the fabric mast envelope.

18. The mechanical electromagnetic field stirrer according to claim 16, wherein the fabric comprises synthetic textile fibers and the inflatable tube comprises polyurethane.

19. The mechanical electromagnetic field stirrer according to claim 16, wherein the framework of the at least one blade is in a shape of an arch comprising at least two parallel arch-shaped elements each containing at least one inflatable tube and connected to each other by at least two elements forming crossmembers, each containing at least one inflatable tube.

20. The mechanical electromagnetic field stirrer according to claim 16, wherein the mechanical electromagnetic field stirrer comprises at least two blades extending radially relative to a central axis of the mast and arranged substantially angularly equidistant from each other.

21. The mechanical electromagnetic field stirrer according to claim 16, wherein the mechanical electromagnetic field stirrer comprises at least two blades having different shapes and/or dimensions.

22. The mechanical electromagnetic field stirrer according to claim 16, wherein the mast has a cylindrical shape and the at least one blade is fastened to a generatrix of the mast by an element of the framework, the mast being provided with fasteners that interact with complementary fasteners on the at least one blade.

23. The mechanical electromagnetic field stirrer according to claim 22, wherein the fasteners on the mast and the complementary fasteners on the at least one blade comprise one or more sliding fasteners.

24. The mechanical electromagnetic field stirrer according to claim 16, wherein the framework of the at least one blade is covered in an electrically conductive material.

25. The mechanical electromagnetic field stirrer according to claim 17, wherein fabric mast envelope is rigidly connected to a rigid plate suitable for being removably fastened to the turntable.

26. The mechanical electromagnetic field stirrer according to claim 16, wherein the chassis is supported by feet that are radially offset outwards relative to a supporting plate.

27. The mechanical electromagnetic field stirrer according to claim 26, wherein the ends of the feet are provided with casters.

28. A method for assembling a mechanical electromagnetic field stirrer for an electromagnetic compatibility test enclosure, the mechanical electromagnetic field stirrer comprising a chassis forming a support for a turntable suitable for being coupled to means for rotating the turntable, a mast mounted on the turntable, and at least one blade of the mechanical electromagnetic field stirrer fastened to the mast and comprising a reflective face, the at least one blade comprising a framework comprising at least one element comprising at least one fabric-based envelope and at least one inflatable tube arranged inside the at least one fabric-based envelope, and the method comprising:
a step of inflating the at least one inflatable tube inside the framework of the at least one blade after having assembled the at least one blade on the mast.

29. The method according to claim 28, wherein the mast comprises a mast envelope that contains an inflatable tube, and the method further comprising:
a step of inflating the at least one inflatable tube situated inside the mast envelope before the mast is fastened to the turntable.

30. The method according to claim 29, wherein the mechanical electromagnetic field stirrer comprises at least first and second blades and the at least first and second blades are inflated.
